(19) United States
(12) Patent Application Publication
(10) Pub. No.: US 2005/0233554 A1
(43) Pub. Date: Oct. 20, 2005

(54) Manufacturing method for semiconductor device and semiconductor manufacturing apparatus

(76) Inventors: Toshihito Tsuga, Tsuchiura (JP); Hirohiko Yamamoto, Hachioji (JP); Michimasa Funabashi, Hachioji (JP); Kazunori Nemoto, Aklshima (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/108,736

(22) Filed: Apr. 19, 2005

(30) Foreign Application Priority Data
Apr. 20, 2004 (JP) 2004-124677

(51) Int. Cl. H01L 21/31

(52) U.S. Cl. 438/482; 438/770; 438/787; 438/488

(57) ABSTRACT

The present invention provides a technology for suppressing occurrence of abnormality on a surface of a silicon film other than a single crystal film formed on a wafer. A silicon film is formed on a wafer in step S1 and an oxide film functioning as an abnormality suppression film for suppressing the surface abnormality is formed on the silicon surface on the wafer formed in step S10. The abnormality suppression film is formed by the surface oxidation of the polycrystalline silicon using chemical solution such as ozone water or hydrogen peroxide solution. After forming the abnormality suppression film on the silicon surface, the abnormality suppression film, for example, an abnormal growth suppression film is removed according to need, and then the process of patterning the silicon film and forming an insulating oxide film is performed.

### CROSS-REFERENCE TO RELATED APPLICATION

The present application claims priority from Japanese Patent Application JP 2004-124677 filed on Apr. 20, 2004, the content of which is hereby incorporated by reference into this application.

### TECHNICAL FIELD OF THE INVENTION

The present invention relates to a technology for suppressing an abnormal growth on a surface of a silicon film other than a single crystal film used for a semiconductor device, that is, an abnormal growth of silicon on a surface of a polycrystalline silicon film and an amorphous silicon film. More particularly, it relates to a technology effectively applied to a single-wafer processing including a step of forming a polycrystalline silicon film.

### BACKGROUND OF THE INVENTION

The technology described below has been examined during the development of the present invention by the inventors thereof, and its outline will be shown as follows.

In a manufacturing process of the semiconductor device, a silicon film (polycrystalline silicon film or amorphous silicon film) is used as a gate electrode material of a MOS transistor and a floating electrode material of a flash memory or the like. For example, after a silicon gate insulating film made of SiO₂ is formed on a silicon surface of a cleaned wafer by thermal oxidation, a silicon film is deposited on the gate insulating film by CVD (Chemical Vapor Deposition) using a silane gas etc. in a nitrogen atmosphere, and then an impurity such as phosphorus is doped into the deposited silicon film. Alternatively, when forming a silicon film, an impurity such as phosphorus is mixed. Thereafter, through a processes of forming a gate electrode pattern by photolithography and the like, the gate electrode is formed.

Japanese Patent Laid-Open No. 2002-305255 discloses the structure of a dual-gate CMOSFET (Complementary Metal Oxide Field Effect Transistor) having a gate electrode formed by implanting an impurity into polycrystalline silicon.

### SUMMARY OF THE INVENTION

As described above, various types of semiconductor devices having the so-called silicon gate electrodes, that is, the gate electrodes formed of silicon films have been suggested and manufactured. However, the polycrystalline silicon used mainly for the silicon gate electrode is formed by the low pressure CVD in which silicon grows under a low pressure condition. In the low pressure CVD, a batch processing is used, in which a large number of wafers are collectively stored and processed in a vertical-type chamber etc.

The inventors of the present invention have found that a phenomenon of the abnormal growth of polycrystalline silicon occurs in the step of forming the polycrystalline silicon in a manufacturing line of a semiconductor device using the single-wafer processing though it does not cause a serious problem in the conventional batch processing.

In the single-wafer processing, the polycrystalline silicon is formed on each of wafers and, for example, a predetermined number of wafers on which the polycrystalline silicon is formed are stored one by one in a FOUP and transferred to the next step. The wafers are taken from the transferred FOUP one by one and, for example, a process for applying a predetermined patterning to the polycrystalline silicon formed on the wafer is performed to each of the wafers.

No particular problem occurs in the normal process flow on the manufacturing line. However, when the line is stopped for the regular cleaning of a clean room or the like, the wafers on which the polycrystalline silicon is formed are left in a standby state in the FOUP for a long time and, in such a standby state, the abnormal growth occurs on the polycrystalline silicon formed on the wafers.

However, leaving the wafers on which the polycrystalline silicon is formed is carried out on a daily basis also in the case of the conventional batch processing, and the time of the standby state of the single-wafer processing is not so much longer than that of the batch processing.

As a result of various examinations of a difference between the batch processing and the single-wafer processing the inventors of the present invention have found the fact as follows. That is, in the usual batch processing, the polycrystalline silicon film is formed on a large number of wafers at a time by the low pressure CVD or the like, and then the wafers are transferred into the air while being maintained in a high temperature. Therefore, the polycrystalline silicon on the wafer naturally reacts with oxygen in the air and an oxide film is formed thereon, and the naturally formed oxide film suppresses the abnormal growth of the polycrystalline silicon.

On the other hand, in the single-wafer processing, the polycrystalline silicon film is formed on each of the wafers, and immediately thereafter the wafer is placed in an enclosed space of the FOUP. Therefore, unlike the batch processing, the time when the wafer is exposed to the air is short, and the highly reactive polycrystalline silicon reacts with the water vapor etc. in the air in the FOUP, and consequently the abnormal growth occurs.

The abnormal growth described above occurs also in the processing other than the single-wafer processing. More specifically, in the batch processing which employs a load lock system in which the processed wafers are not directly exposed to the air or in the batch processing in which the processed wafers are withdrawn under an N₂ atmosphere, the natural oxide film is not formed. Therefore, the above-described problem similarly to the single-wafer processing probably occurs.

The study by the inventors of the present invention has found that the problem of the abnormal growth occurs when the wafers are left in the FOUP for at least six hours. Obviously, the starting time of the abnormal growth of the polycrystalline silicon greatly varies depending on an amount of phosphorus doped into the polycrystalline silicon, the water content in the atmosphere in the FOUP in which the wafers are stored, and the like. Therefore, it is impossible to assure that the abnormal growth of polycrystalline silicon which causes a problem does not occur if the time is six hours or less.

If the line of the single-wafer processing is properly operated, the abnormal growth of the polycrystalline silicon does not cause any problem. However, there is much possibility that the line is stopped for six hours or more due to the trouble of apparatus. If the abnormal growth of polycrystalline silicon formed on the wafer occurs in every line stop and the like, the percent of product defect becomes extremely high and the throughput is significantly reduced, which greatly influences the production efficiency.

Also, the above-described abnormal growth of polycrystalline silicon occurs also in an event other than the transition to the next step. For example, even in the case where the polycrystalline silicon is patterned in the latter step, there is a strong possibility that the abnormal growth will occur during the time when the surface of the polycrystalline silicon is exposed to the surrounding atmosphere. A fluorine-based gas such as SF₆ is used in the patterning of the polycrystalline silicon. However, if the polycrystalline silicon having the fluorine-based gas left on the surface thereof is exposed to the air, the abnormal growth easily occurs even in a short time.

FIG. 1 shows an example of the abnormal growth of polycrystalline silicon formed on the wafer. FIG. 1 is a photograph showing the abnormal growth of the polycrystalline silicon generated in the following manner. That is, after forming an etching mask by a resist, etching by the etching mask, and removing the etching mask by ashing are performed for the polycrystalline silicon doped with phosphorus in the photolithography process, the polycrystalline silicon is left for a long time of six hours or more. A protrusion of a spherical foreign matter with a dimension of about 1 μm is formed on the polycrystalline silicon. The spherical foreign matter formed due to the abnormal growth cannot be removed by the subsequent cleaning, which causes critical failure.

An object of the present invention is to suppress the occurrence of film surface abnormality, for example, an abnormal growth on a silicon film formed on a wafer.

The above and other objects and novel characteristics of the present invention will be apparent from the description of this specification and the accompanying drawings.

The typical ones of the inventions disclosed in this application will be briefly described as follows.

More specifically, in the present invention, after forming a silicon film, an oxide film is formed on the surface within a predetermined time or the next process is executed within a predetermined time so as to prevent the occurrence of the abnormal growth on the film surface. The surface of the polycrystalline silicon or amorphous silicon is forcibly oxidized by using oxidation means such as ozone water immediately after forming the polycrystalline silicon or amorphous silicon on the wafer without relying on the natural oxidation. By doing so, the surface abnormality of a film can be suppressed.

The effect obtained by the representative one of the inventions disclosed in this application will be briefly described as follows.

According to the present invention, even in the single-wafer processing different from the batch processing, the abnormal growth of polycrystalline silicon or amorphous silicon formed on the wafer can be suppressed.

### BRIEF DESCRIPTIONS OF THE DRAWINGS

FIG. 1 is a photograph showing an appearance of abnormal growth of polycrystalline silicon.

FIG. 2 is a flowchart showing an example of a procedure of a process in which occurrence of the abnormal growth of silicon after forming polycrystalline silicon is suppressed by controlling a standby time in a manufacturing method of a semiconductor device.

FIG. 3A is a flowchart showing an example of the procedure of the manufacturing method of a semiconductor device according to an embodiment of the present invention.

FIG. 3B is a flowchart showing the procedure of a conventional manufacturing method corresponding to that of FIG. 3A.

FIG. 4 is a cross-sectional view schematically showing an appearance in which an abnormal growth suppression film is formed on polycrystalline silicon formed on a wafer.

FIG. 5 is a flowchart showing an example of the procedure of the manufacturing method of a semiconductor device according to an embodiment of the present invention.

FIG. 6 is a flowchart showing an example of the procedure of the manufacturing method of a semiconductor device according to the embodiment of the present invention.

FIG. 7A is a cross-sectional view schematically showing a sectional structure of a semiconductor device manufactured in accordance with the manufacturing method of a semiconductor device according to the present invention.

FIG. 7B is a partial cross-sectional view showing a state where an oxide film formed on polycrystalline silicon is absorbed by metal in contact with the oxide film.

FIG. 8 is an explanatory diagram schematically showing an example of a configuration of a semiconductor manufacturing apparatus according to an embodiment of the present invention.

FIG. 9 is an explanatory diagram schematically showing a modified example of the configuration of the semiconductor manufacturing apparatus according to an embodiment of the present invention.

FIG. 10 is an explanatory diagram schematically showing a modified example of the configuration of the semiconductor manufacturing apparatus according to an embodiment of the present invention.

FIG. 11 is a cross-sectional view schematically showing a sectional structure of a TFT used for a liquid crystal display manufactured in accordance with the manufacturing method of a semiconductor device according to the present invention.

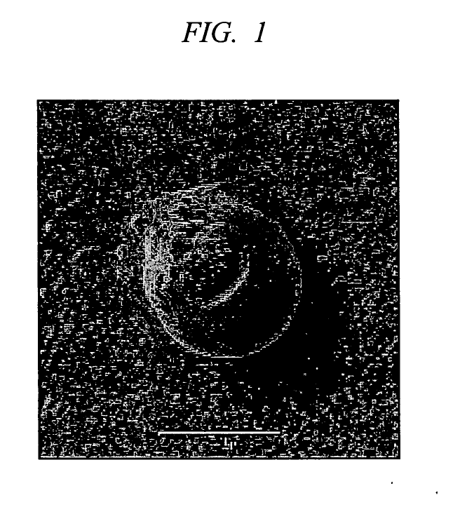

### DESCRIPTION OF THE PREFERRED EMBODIMENTS

Hereinafter, embodiments of the present invention will be described in detail with reference to the accompanying drawings Note that components having the same function are denoted by the same reference symbols throughout the drawings for describing the embodiment, and the repetitive description thereof is omitted.

### First Embodiment

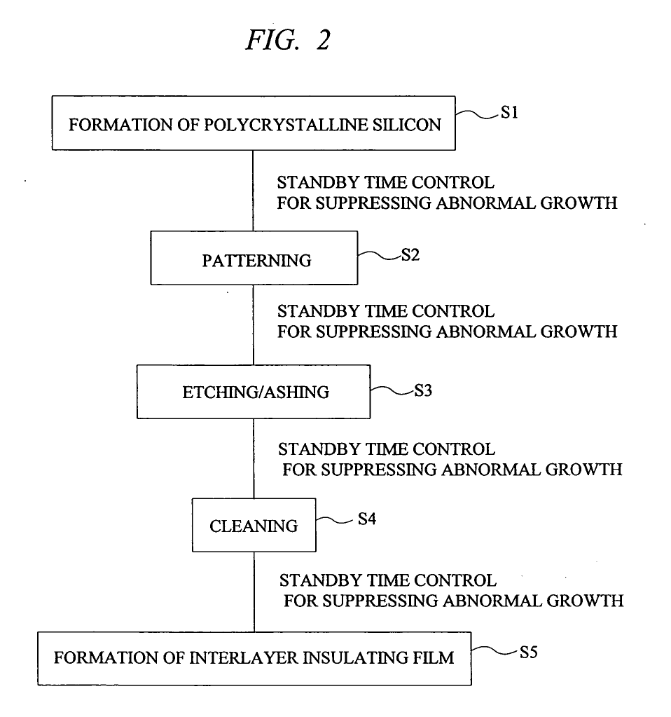

For the suppression of the abnormal growth on a surface of a polycrystalline silicon film formed on a wafer, a manufacturing method of a semiconductor device according to the present invention will be described in this embodiment in which a standby time is controlled so as to minimize the occurrence of the abnormal growth in the single-wafer processing of polycrystalline silicon as shown in FIG. 2.

More specifically, in the process shown in FIG. 2, a polycrystalline silicon film is formed on a wafer by CVD in step S1. In step S2, the formed polycrystalline silicon film is patterned. For example, a photosensitive resist is formed on the polycrystalline silicon, the resist is exposed using a predetermined pattern and then is developed to form an etching mask, and the polycrystalline silicon is patterned by the etching using a fluorine-based gas etc. along the etching mask.

In step S3, the etching mask is removed by the etching using the fluorine-based gas and then is completely removed by the ashing. After the removal, it is cleaned in step S4. Then, in step S5, an interlayer insulating film (SiO₂) is formed on the patterned polycrystalline silicon, or a capacitor oxide film (SiO₂/Si₃N₄/SiO₂) or the like is laminated thereon.

If each of the standby times between the steps 1 and 2, between the steps 2 and 3, between the steps 3 and 4, and between the steps 4 and 5 can be controlled so as to be limited within a predetermined time for preventing the abnormal growth from occurring, the abnormal growth described above can be sufficiently suppressed.

More specifically, in order to prevent the abnormal growth on the surface of the polycrystalline silicon film, a transfer time to the next step after forming the polycrystalline silicon film is set to be short enough to prevent the occurrence of the abnormal growth. In this time setting, it is preferable to set the time in which the occurrence of the abnormal growth is physically impossible. That is, the time setting capable of completely preventing the occurrence of the abnormal growth is preferable.

However, depending on processing conditions etc., the abnormal growth may occur in an extremely short time after forming the polycrystalline silicon film. Therefore, the allowable abnormal growth, which does not cause any trouble in the latter process and does not adversely influence the characteristics of the semiconductor device, can be considered as the substantially negligible one, and the time setting taking the above-described point into consideration is also preferable. For example, the above-described time short enough to prevent the occurrence of the abnormal growth is defined as the time short enough to prevent the occurrence of the abnormal growth which causes the trouble in the latter process or which adversely influences the characteristics of the semiconductor device.

Note that the method of controlling the standby time is not limited to the case of forming polycrystalline silicon on the wafer. For example, it can be also effectively applied to the case of forming amorphous silicon.

### Second Embodiment

In a second embodiment, the case where a manufacturing method for a semiconductor device according to the present invention is applied to the suppression of the abnormal growth of polycrystalline silicon formed on the wafer will be described.

In the first embodiment, the method of preventing the abnormal growth of silicon by controlling the standby time of each step, that is, by setting the standby time to be short enough to prevent the occurrence of the abnormal growth on a film surface has been described. However, depending on on-site conditions, the time control as described above is sometimes difficult. Furthermore, when any of the steps is stopped due to the line trouble or the like, the predetermined standby time may be extended and the time control as planned cannot be performed in some cases.

Therefore, as a method for suppressing the surface abnormality of silicon other than the above-described method of controlling the standby time, in which the next process is performed before the occurrence of the surface abnormality of silicon, the inventors of the present invention have found that a method of forcibly oxidizing the surface before the transition to the next step, that is, immediately after forming a silicon film is effective. This method will be described in the second embodiment.

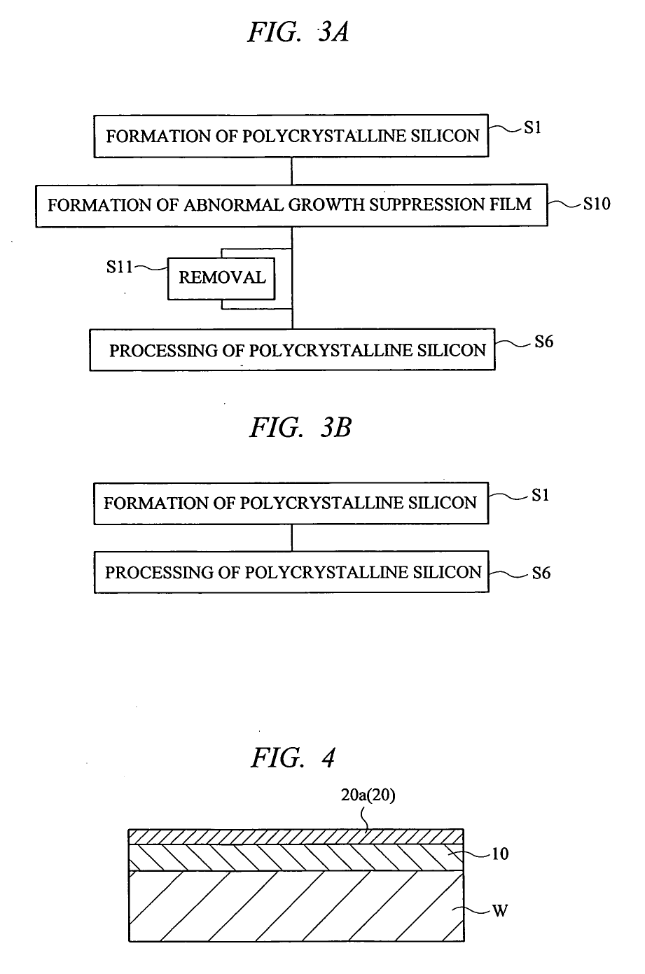

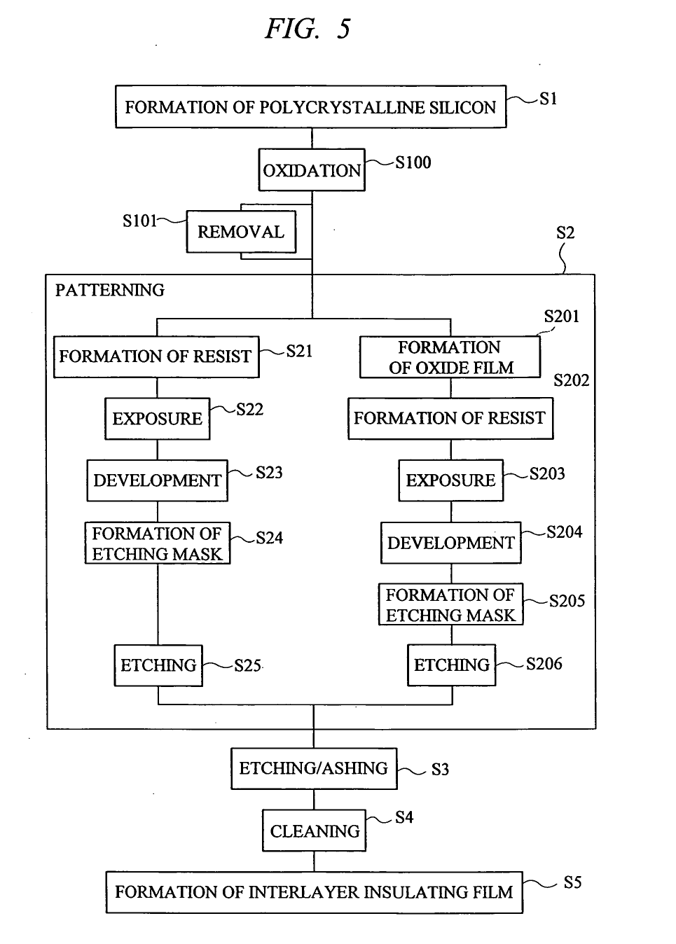

FIG. 3A is a flowchart showing an example of a procedure of the manufacturing method of a semiconductor device according to the present invention, in which a step of forming a film for suppressing the abnormal growth (hereinafter referred to as “abnormal growth suppression film”) of polycrystalline silicon is provided. FIG. 3B is a flowchart showing an example of a procedure of a conventional manufacturing method for a semiconductor device, in which a step of forming a film for suppressing the abnormal growth of polycrystalline silicon is not provided. FIG. 4 is a cross-sectional view schematically showing a state where an abnormal growth suppression film is formed on a polycrystalline silicon film formed on the wafer. FIG. 5 is a flowchart showing an example of the procedure of the manufacturing method for a semiconductor device according to the present invention, in which a step of performing an oxidation process which is effective for the suppression of the abnormal growth of polycrystalline silicon is provided.

The manufacturing method of a semiconductor device according to the present invention can be effectively applied to the manufacturing method of a semiconductor device including a step of forming the polycrystalline silicon film on the wafer. More particularly, it can be effectively used in the single-wafer processing in which a natural oxide film with a sufficient thickness is hardly formed on the surface of polycrystalline silicon formed on the wafer unlike the batch processing.

Similarly, it can be effectively used in the batch processing which employs the load lock system in which the wafers are not directly exposed to the air after forming the polycrystalline silicon film or the batch processing in which the wafers are withdrawn under the N₂ atmosphere after forming the polycrystalline silicon film.

As shown in FIG. 3A, the manufacturing method for a semiconductor device according to the present invention includes: the step S1 for forming the polycrystalline silicon film on the wafer; and a step S10 immediately after the step S1, in which the abnormal growth suppression film for suppressing the abnormal growth of polycrystalline silicon is formed on the polycrystalline silicon formed in the step S1.

In the step S10 for forming the abnormal growth suppression film, the surface of the polycrystalline silicon film formed in the step S1 is oxidized to cover the surface of the polycrystalline silicon film with another oxide film so as not to directly expose the surface of the polycrystalline silicon film to the surrounding air. As described above, the polycrystalline silicon is highly reactive. When the polycrystalline silicon comes into contact with the air, phosphorus doped into the polycrystalline silicon reacts with the water vapor in the air to form phosphoric acid and the phosphoric acid reacts with silicon. As a result, the abnormal growth occurs. However, the occurrence of the abnormal growth can be effectively suppressed by covering the surface of polycrystalline silicon with the abnormal growth suppression film made of an oxide film or the like.

TABLE 1

| | Number of defects just | |
|---|---|---|
| | after deposition of | Number of defects |
| | polycrystalline silicon | after 10 days |
| (1) Not processed | 15 pcs/wf | >10000 pcs/wf |
| (2) O₃ processed | 20 pcs/wf | 22 pcs/wf |

The table 1 shows effectiveness in the case where the abnormal growth suppression film is formed on polycrystalline silicon by using the manufacturing method of a semiconductor device according to the present invention. More specifically, the table 1 shows a comparison result of the abnormal growth of polycrystalline silicon between the case where the polycrystalline silicon film doped with phosphorus is formed on the wafer and is left for 10 days (“Not processed” in the table) and the case where the oxidation process using ozone water of 20 ppm for 10 seconds is performed to the surface of the polycrystalline silicon film to form the abnormal growth suppression film made of an oxide film and then the polycrystalline silicon film is left for 10 days (“O₃ processed” in the table).

As is apparent from the table 1, the defects resulting from the abnormal growth in the level of 10000 pcs/wf are found in the case where the polycrystalline silicon is left without forming the abnormal growth suppression film. On the other hand, the number of defects in the case where the abnormal growth suppression film is formed and then the polycrystalline silicon film is left is almost equal to that immediately after forming the polycrystalline silicon film. Therefore, it is effective for the suppression of the abnormal growth to form the oxide film after forming the polycrystalline silicon film.

After forming the abnormal growth suppression film in the step S10, processing for the polycrystalline silicon such as the patterning for forming a gate electrode is performed in the step S6. If the abnormal growth suppression film formed in the step S10 exerts an adverse effect on the processing for the polycrystalline silicon in the step S6, it is possible to remove the abnormal growth suppression film in the step S11 as shown in FIG. 3A. Also, when the abnormal growth suppression film does not cause any trouble in the latter process and does not adversely influence the characteristics of the semiconductor device, it is possible to leave the abnormal growth suppression film without removing it in the step S11.

FIG. 4 is a cross-sectional view schematically showing a state where an abnormal growth suppression film 20 such as an oxide film 20a is formed on a polycrystalline silicon film 10 on a wafer W.

In the process for forming a polycrystalline silicon film in the conventional manufacturing method of a semiconductor device, the step for suppressing the abnormal growth of polycrystalline silicon is not provided between the steps S1 and S6 as shown in FIG. 3B. Therefore, in the case where polycrystalline silicon is formed and the polycrystalline silicon is processed under the condition of the single-wafer processing, the abnormal growth occurs. However, when the procedure of the manufacturing method for a semiconductor device according to the present invention shown in FIG. 3A is applied, the abnormal growth of polycrystalline silicon can be effectively suppressed even in the single-wafer processing in which the abnormal growth frequently occurs under normal circumstances.

The reason why the abnormal growth of polycrystalline silicon does not become apparent in the batch processing is that the polycrystalline silicon is placed in the situation that the surface thereof is naturally oxidized. However, the procedure shown in FIG. 3A can be applied not only to the single-wafer processing but also to the batch processing. For example, when the wafer having the polycrystalline silicon formed thereon is processed under the condition that the abnormal growth easily occurs in the batch processing, the procedure shown in FIG. 3A can be effectively applied.

More specifically, it can be effectively used in the batch processing which employs the load lock system in which the wafers are not directly exposed to the air after forming the polycrystalline silicon film and the batch processing in which the wafers are withdrawn under the N₂ atmosphere after forming the polycrystalline silicon film.

FIG. 5 shows the manufacturing method of a semiconductor device according to the present invention in more detail. More specifically, in the step S1, the polycrystalline silicon film is formed on the wafer by CVD or the like. After forming the polycrystalline silicon film, the surface of the polycrystalline silicon film is oxidized in the step S100. This surface oxidation forms an oxide film on the polycrystalline silicon film, and the oxide film functions as the abnormal growth suppression film of the polycrystalline silicon as described above.

Basically, any means such as physical means and chemical means can be used for the oxidation in the step S100 as long as it can oxidize the polycrystalline silicon film. However, the inventors of the present invention determine that the oxidation process using ozone water and the chemical solution process using hydrogen peroxide solution as an oxidizing agent are preferable from the viewpoint of the process time, the process cost, the process safety and the like.

For example, when the ozone water is used for the oxidation step in the step S100, the ozone water (also referred to as ozone added water or ozone dissolved water) obtained by dissolving ozone into purified water or ultrapure water is available. A ozone concentration of 5 ppm or higher is preferable. The concentration of 5 ppm or lower is not preferable because the reaction will be slow and insufficient when considering the tact time for transferring the processed wafer to the next step in the single-wafer processing.

When the concentration is 5 ppm, the oxidation process to form an oxide film with a thickness of about 0.8 nm is finished in about 20 seconds. When it is 20 ppm, the oxidation process is finished in about 10 seconds. As described above, the ozone water makes it possible to finish the oxidation process in an extremely short time.

Note that, in the batch processing employing the load lock system and the batch processing in which the wafers are withdrawn under the N₂ atmosphere, the concentration of ozone water lower than 5 ppm is also available because the strict consideration of the tack time is not required in comparison to the single-wafer processing.

Also, since the ozone water can be decomposed into water and oxygen which do not affect the environment, it is effective from the viewpoint of the environmental measures at the time of disposal.

Also, when chemical solution is used in the oxidation process in the step S100, for example, hydrogen peroxide solution is preferably used. In a field of the semiconductor device manufacturing, the hydrogen peroxide solution is used as cleaning solution of a wafer and as slurry in the chemical mechanical polishing. Therefore, since the applicability of hydrogen peroxide solution in the manufacture of a semiconductor device has been sufficiently verified, it is possible to use the hydrogen peroxide solution with a sense of security. In addition, since the hydrogen peroxide solution has been used so far, it is advantageous from the viewpoint of the supply cost.

Furthermore, since the hydrogen peroxide solution is decomposed into water and oxygen, it is preferable from the viewpoint of the environmental measures at the time of disposal similar to the ozone water. Of course, if the consideration as described above is not particularly required, the chemical solution having the oxidizing properties other than the hydrogen peroxide solution is also available. For example, AMP (NH₄OH/H₂O₂/H₂O) or HPM (HCl/H₂O₂/H₂O) used as cleaning solution is available.

As shown in FIG. 5, in the manufacturing method of a semiconductor device according to the present invention, the oxidation process of the polycrystalline silicon is usually provided before the patterning process of the polycrystalline silicon. More specifically, it is necessary to provide the step S100 for the oxidation process after forming the polycrystalline silicon on the wafer and before performing a step of, for example, forming a film on the polycrystalline silicon. The oxidation process in the step S100 is provided for the purpose of suppressing the occurrence of the abnormal growth caused when the highly reactive polycrystalline silicon film is directly exposed to the air and the like. In this sense, it is necessary to provide the oxidation process as a step immediately after forming the polycrystalline silicon film.

Also, the oxide film formed in order to suppress the abnormal growth of the polycrystalline silicon in the step S100 is not required to have a thickness equal to that of the usual interlayer insulating film and the hard mask used as a resist. That is, in the case of a current doping amount of phosphorus (1×10²⁰ atoms/cm³ level) to the polycrystalline silicon, the suppression of the abnormal growth of polycrystalline silicon can be sufficiently achieved if at least the thickness of monolayer equivalent to a single layer of atoms can be ensured.

Strictly, the thickness of the oxide film required to function as the abnormal growth suppression film varies depending on the amount of phosphorus doped into the polycrystalline silicon. However, from the viewpoint of the current doping amount of phosphorus into the polycrystalline silicon, the thickness of monolayer is sufficiently set as a lower limit thereof.

Of course, when the doping amount of phosphorus smaller than the current doping amount is employed, the thickness of the oxide film functioning as the abnormal growth suppression film can be made smaller than the thickness of the monolayer. For example, the oxide film with a thickness of 0.2 or 0.3 nm may be available.

As shown in FIG. 5, after forming the oxide film functioning as the abnormal growth suppression film on the surface of the polycrystalline silicon film formed on the wafer, the wafer is transferred to the step S2, in which the patterning of the polycrystalline silicon is performed. By doing so, it is possible to effectively suppress the abnormal growth of polycrystalline silicon before the patterning process.

For example, as shown in a series of steps of S21 to S25, in the case where the polycrystalline silicon is patterned by the photolithography using a resist, for example, after forming an oxide film having a function as the abnormal growth suppression film in the step S100, the oxide film is removed by the etching in the step S101. Even when the oxide film is removed in the step S101, the patterning process can be performed before the occurrence of the abnormal growth of polycrystalline silicon in the subsequent step unless the standby time is long more than necessary.

After the removal of the oxide film in the step S101, a photosensitive resist is coated on the polycrystalline silicon in the step S21. The resist is exposed to light through a reticle in the step S22 and is developed in the step S23. Then, an etching mask used for patterning the polycrystalline silicon film is formed in the step S24. The etching of the polycrystalline silicon film is performed with using the etching mask in the step S25.

After the patterning of the polycrystalline silicon, the etching mask is completely removed by the etching using fluorine-based gas and the ashing. After the removal of the etching mask, the wafer is cleaned in the step S4, and an interlayer insulating film (SiO₂) and the like are formed on the patterned polycrystalline silicon in the subsequent step S5.

As described above, by using the manufacturing method of a semiconductor device according to the present invention, even when the standby time becomes longer than, for example, six hours after forming the polycrystalline silicon film in the case where the polycrystalline silicon is patterned by using the resist, since an oxide film is formed on the polycrystalline silicon, the occurrence of the abnormal growth of the polycrystalline silicon before the patterning process which causes the defects can be sufficiently suppressed.

Note that the case where the oxide film functioning as the abnormal growth suppression film formed on the polycrystalline silicon film is removed in the step S101 has been described in the foregoing description. However, it is also possible to leave the oxide film functioning as the abnormal growth suppression film without removing it in the step S101 if the abnormal growth suppression film does not cause any trouble in the latter process and does not adversely influence the characteristics of the function of the semiconductor device. In the case where the oxide film is not removed, both of the oxide film functioning as the abnormal growth suppression film and the polycrystalline silicon film are etched in the step S25. The inventors of the present invention make sure that there is no problem in the usual processing if the abnormal growth suppression oxide film has a thickness smaller than 2 nm.

Next, the case where the silicon oxide film is used as the etching mask instead of the etching mask formed of a resist will be described. Also in such a case, the polycrystalline silicon film is formed on the wafer in the step S1 as shown in FIG. 5. Then, the oxide film functioning as the abnormal growth suppression film is formed on the polycrystalline silicon film formed in the step S100. Thereafter, the procedure proceeds to the patterning step of polycrystalline silicon in the step S2 without removing the oxide film on the polycrystalline silicon film.

In the patterning step of polycrystalline silicon in the step S2, the oxide film for forming the etching mask for the polycrystalline silicon is formed in the step S201. More specifically, the thickness of the oxide film formed in the step S100 is increased to a predetermined value. Then, in the step S202, a photosensitive resist is coated on the oxide film formed in the step S100. The resist is exposed to light through the reticle in the step S203 and developed in the step S204. Thereafter, the etching mask made of the oxide film and used for patterning the polycrystalline silicon film is formed in the step S205. In the step S206, the etching of the polycrystalline silicon film is performed with using the etching mask.

After the patterning of the polycrystalline silicon, similarly to the case described above, the etching mask is completely removed by the etching using the fluorine-based gas and the ashing in the step S3. After the removal of the etching mask, the wafer is cleaned in the step S4, and the interlayer insulating film (SiO₂) and the like are formed on the patterned polycrystalline silicon in the subsequent step S5.

In the above-described case where the oxide film is used as the etching mask for the patterning of the polycrystalline silicon, the oxidation process in the step S100 for forming the oxide film functioning as the abnormal growth suppression film seems to overlap with the oxide film forming step in the step S201. However, this procedure is more effectively applied when the process time for forming the oxide film functioning as the etching mask on the polycrystalline silicon film is longer than the process time for forming the polycrystalline silicon film on the wafer.

More specifically, when there is a difference between the process times as described above, the wafer having the polycrystalline silicon film formed thereon in the step S1 is inevitably awaited in the FOUP or the like before transferred into the means for forming the oxide film used to form the etching mask in the step S201. Therefore, there is the possibility that the abnormal growth will occur on the polycrystalline silicon film before the transition to the step S202. For its prevention, as shown in FIG. 5, the step S100 is provided before the step S201 so as to suppress the abnormal growth of the polycrystalline silicon during the standby time.

In addition, depending on the situation, it is also possible to remove the oxide film functioning as the abnormal growth suppression film in the step S101 before the transition to the step S201.

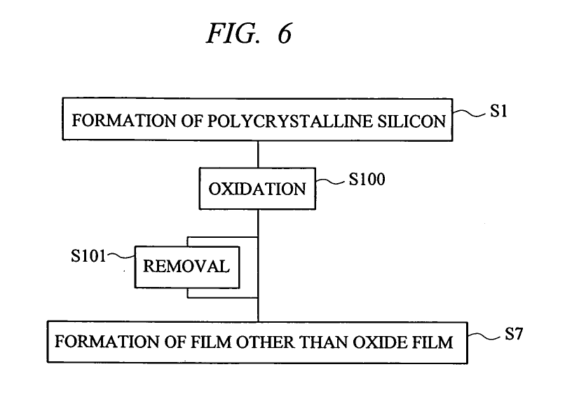

In the foregoing description, in the case where the polycrystalline silicon film formed on the wafer is patterned, the oxide film functioning as the abnormal growth suppression film is formed before the patterning step, that is, immediately after forming the polycrystalline silicon film. However, the manufacturing method of a semiconductor device according to the present invention can be effectively applied to the case where a film other than the oxide film is deposited on the polycrystalline silicon film formed on the wafer as shown in FIG. 6.

In the case shown in FIG. 6, the polycrystalline silicon film is formed on the wafer by the CVD in the step S1. Thereafter, in the step S100, the surface of the polycrystalline silicon film formed in the step S1 is oxidized to form the oxide film functioning as the abnormal growth suppression film on the polycrystalline silicon film. Then, the oxide film is removed in the step S101, and a film other than an oxide film such as a tungsten suicide (WSi) film is formed on the polycrystalline silicon film in the step S7.

Note that, it is also possible to leave the oxide film functioning as the abnormal growth suppression film without removing it if it does not adversely influence the latter process and the characteristics of the semiconductor device.

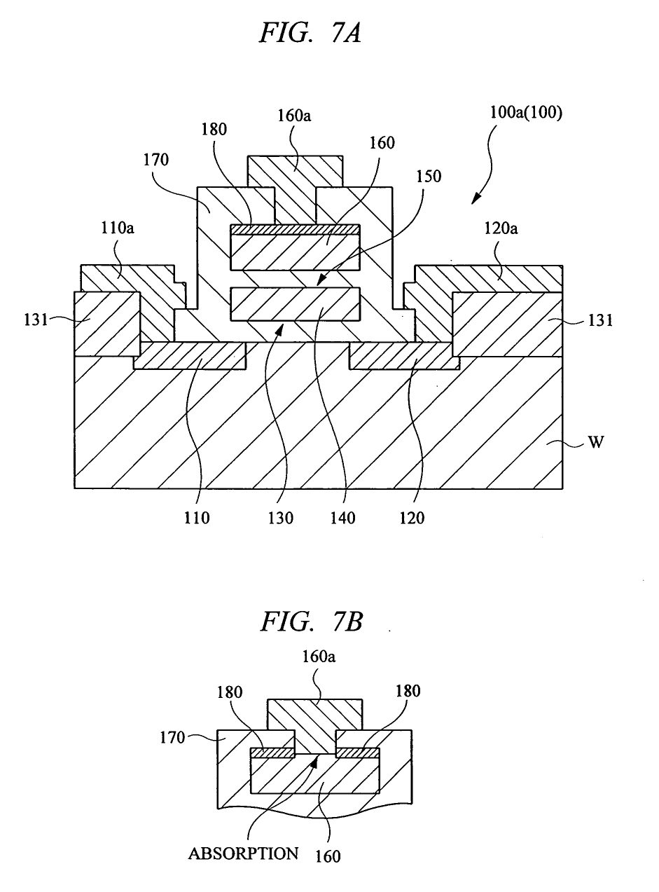

FIG. 7A schematically shows an example of a structure of a semiconductor device in which the polycrystalline silicon film formed on the wafer in accordance with the above-described method is used as a gate electrode. More specifically, FIG. 7A shows an example of a semiconductor device 100 to be used as a flash memory 100a.

A source (N⁺) region 110 and a drain (N⁺) region 120 are formed on a P type Si substrate of a wafer W, and a source electrode 110a made of aluminum (Al) and a drain electrode 120a made of aluminum (Al) are formed for each region via contacts.

A first gate oxide film (tunnel oxide film) 130 is formed for both of the source region 110 and the drain region 120, and a floating gate 140 is formed in the first gate oxide film 130 extending across both regions. Field oxide films 131 are formed in the manner as shown in FIG. 7A.

A control gate 160 is formed so as to be opposed to the floating gate 140 with a second gate oxide film 150 functioning as a capacitor interposed therebetween, and a control gate electrode 160a made of aluminum (Al) is formed via a contact on the control gate 160 surrounded by an interlayer insulating film 170.

In the flash memory 100a with the above-described structure, the floating gate 140 and the control gate 160 are formed of polycrystalline silicon. In the case shown in FIG. 7A, the oxide film functioning as the abnormal growth suppression film is removed on the floating gate 140 made of polycrystalline silicon, and an oxide film 180 functioning as the abnormal growth suppression film is not removed on the control gate 160 made of polycrystalline silicon.

More specifically, when the polycrystalline silicon film formed on the wafer is patterned to form the floating gate, the oxide film formed in the step S100 by the oxidation means using ozone water which functions as the abnormal growth suppression film on the polycrystalline silicon film is removed in the step S101 as shown in FIG. 4. On the other hand, in the process of forming the control gate 160, when the polycrystalline silicon film is patterned to form the control gate, the oxide film 180 formed in the step S100 by the oxidation means using ozone water which functions as the abnormal growth suppression film is not removed and is processed.

Note that since the oxide film 180 can function as the abnormal growth suppression film if it has the thickness almost equal to that of monolayer, the thickness of the oxide film 180 is far smaller than that of the usual interlayer insulating film and the like. Therefore, there is the possibility that the oxide film 180 is absorbed into the reducing metal when the oxide film 180 comes into contact with the reducing metal. Consequently, the oxide film 180 is not always obviously recognized unlike in the cross-sectional view shown in FIG. 7A. For example, as shown in FIG. 7B, the oxide film 180 left on the polycrystalline silicon of the control gate 160 is partly absorbed into Al of the control gate electrode 160a, and the oxide film 180 cannot be obviously recognized in some cases.

### Third Embodiment

In a third embodiment, based on the manufacturing method of a semiconductor device described in the second embodiment, the semiconductor manufacturing apparatus capable of forming the abnormal growth suppression film with the same effects as described in the second embodiment by using the gas functioning as the oxidizing agent instead of the liquid oxidizing agent such as the ozone water and the hydrogen peroxide solution will be described.

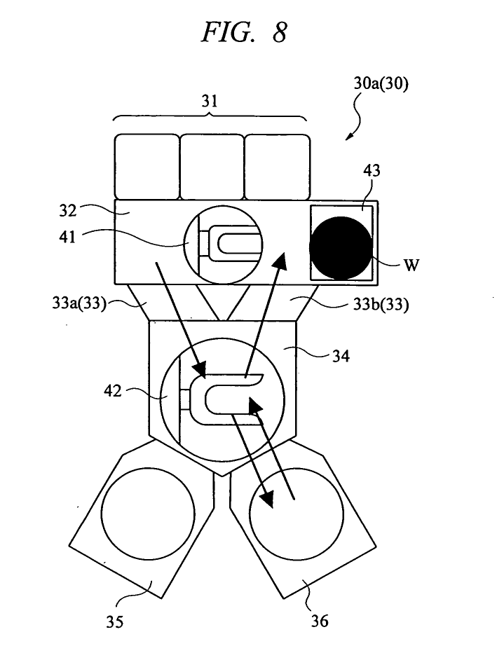

FIG. 8 is an explanatory diagram schematically showing the semiconductor manufacturing apparatus 30 according to the present invention represented by the CVD apparatus (Chemical Vapor Deposition apparatus) 30a used as the multi-chamber polycrystalline silicon forming apparatus.

As shown in FIG. 8, the CVD apparatus 30a is provided with a load port 31 at which the wafer is transferred from the previous step and to the next step. A plurality of wafers are collectively stored in a wafer storing unit such as a FOUP and, in this state, the wafers are automatically transferred from the previous step and to the next step by a transfer robot through the load port 31.

The load port 31 is located next to an air loader chamber 32, and the air loader chamber 32 is connected to a transfer chamber 34 via a load lock 33. In the case shown in FIG. 8, the load lock 33 comprises an outward load lock 33a exclusively used when the wafer W is transferred from the air loader chamber 32 to the transfer chamber 34 and a homeward load lock 33b exclusively used when the wafer W having the polycrystalline silicon film formed thereon is returned from the transfer chamber 34 to the air loader chamber 32.

The homeward load lock 33b is provided with a supply port of oxygen so that the wafer W passing through the homeward load lock 33b is exposed to the high-concentration oxygen atmosphere. More specifically, the homeward load lock 33b functions as the oxidation means of the wafer W after the polycrystalline silicon film is formed. The outward load lock 33a is not provided with the oxygen supply port described above.

The air loader chamber 32 is provided with a transfer robot 41, and the wafer W is transferred between the transfer robot 41 and a transfer robot 42 provided in the transfer chamber 34 via an aligner 43 provided in the air loader chamber 32. The transfer chamber 34 is connected to process chambers 35 and 36. In the process chambers 35 and 36, the chemical vapor growth means is provided as the polycrystalline silicon forming means which forms the polycrystalline silicon film on the wafer W.

Though not shown, the chemical vapor growth means has the configuration as follows. That is, a supply port and an exhaust port for a material gas are provided in each of the process chambers 35 and 36, in which the supplied material gas is heated to a predetermined temperature, and polycrystalline silicon is deposited by the chemical vapor growth on the wafer W held by a wafer chuck in the chamber. The transfer chamber 34 and the process chambers 35 and 36 are connected to a vacuum exhaust system (not shown) so as to maintain the predetermined low-pressure condition.

In the multi-chamber CVD apparatus 30a with the configuration described above, an oxide film capable of suppressing the abnormal growth of polycrystalline silicon can be formed immediately after forming the polycrystalline silicon film on the wafer W. The polycrystalline silicon film and the abnormal growth suppression film are formed on the wafer in the same apparatus in the following manner.

First, the plurality of wafers W stored in the FOUP are transferred from the previous step to the load port 31 of the CVD apparatus 30a. Each one wafer W held by the transfer robot 41 is taken from the FOUP placed on the load port 31 and carried to the transfer robot 42 in the transfer chamber 34 through the outward load lock 33a. The transfer robot 42 places the carried wafer W on the wafer chuck in the process chamber 35.

When the wafer W is held on the wafer chuck, a door between the process chamber 35 and the transfer chamber 34 is closed, and the pressure is reduced to a predetermined pressure. Then, the material gas heated to a predetermined temperature passes on the wafer W in the chamber, thereby forming the polycrystalline silicon film on the wafer W.

When the polycrystalline silicon film is formed on the wafer W in the process chamber 35, another wafer W is transferred to the adjacent process chamber 36 in the same manner as described above, and then the process of forming a polycrystalline silicon film is started.

During the time when the polycrystalline silicon film is formed on the wafer W in the process chamber 36, the process for forming a polycrystalline silicon film in the process chamber 35 is finished, and the door of the transfer chamber 34 is opened. Then, the wafer W held by the wafer chuck is taken out by the transfer robot 42 and carried to the transfer robot 41 via the aligner 43 in the air loader chamber 32 through the homeward load lock 33b.

When the wafer W on which the polycrystalline silicon film is formed passes through the homeward load lock 33b, the still high-temperature wafer W is exposed to the high-concentration oxygen supplied to the homeward load lock 33b. Consequently, the surface of the polycrystalline silicon film is immediately oxidized, and the oxide film functioning as the abnormal growth suppression film is formed.

The wafer W having the oxide film functioning as an abnormal growth suppression film formed on the surface of the polycrystalline silicon is stored in the FOUP placed on the load port 31 by the transfer robot 41. When a predetermined number of wafers W having the abnormal growth suppression film formed on the surface of the polycrystalline silicon are stored in the FOUP, the wafers W are transferred to a next step such as the patterning of the polycrystalline silicon and the like. Alternatively, the wafers W are awaited for a predetermined time.

Since the CVD apparatus 30a according to the present invention has both of the means for forming polycrystalline silicon on the wafer and the oxidation means for forming the oxide film on the surface of the polycrystalline silicon immediately after forming the polycrystalline silicon film, the occurrence of the abnormal growth of polycrystalline silicon can be effectively suppressed by covering the surface of the polycrystalline silicon with the formed oxide film. Also, since the oxidation means is provided in the apparatus for forming the polycrystalline silicon film, the oxide film can be successively formed in a short time after forming the polycrystalline silicon film in comparison to the case where the oxidation means is provided in the separate apparatus.

In the case shown in FIG. 8, the load lock 33 is separated into the outward and homeward load locks. However, the configuration including the load lock used to transfer a wafer W between the air loader chamber and the transfer chamber is also known. In this case, the supply of the high-concentration oxygen can be controlled so that it is supplied only when the wafer is returned.

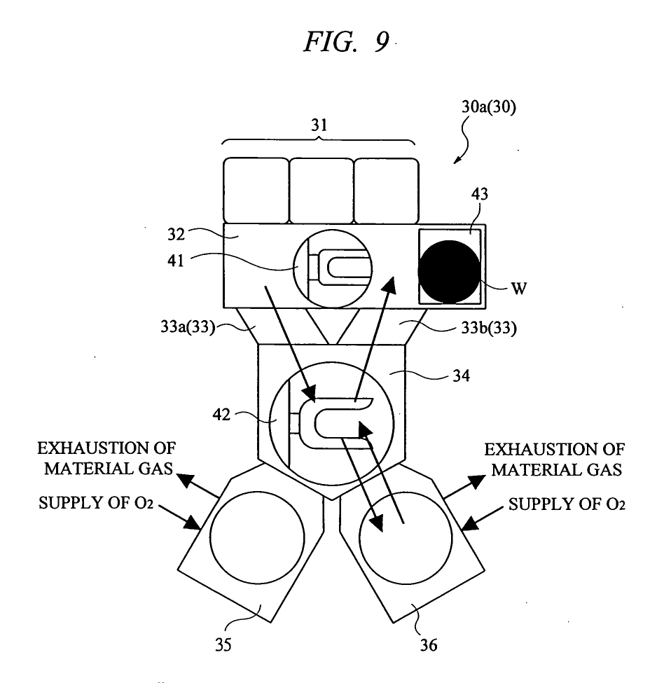

In the CVD apparatus 30a shown in FIG. 9, since oxygen is supplied into the process chambers 35 and 36, the oxidation process can be performed in the same chamber after forming the polycrystalline silicon film on the wafer. For example, at the time when the polycrystalline silicon film is formed in the process chambers 35 and 36, the material gas such as SF₄ is completely exhausted through the exhaust system connected to the process chambers 35 and 36, and then an oxygen gas is supplied through the material supply system. In this manner, the process for forming the polycrystalline silicon film and the process for forming the oxide film immediately after forming the polycrystalline silicon film can be successively performed in the same chamber. After forming the oxide film, oxygen is exhausted through the exhaust system, and the material gas is supplied through the supply system to form the polycrystalline silicon film on another wafer. More specifically, the process for forming the polycrystalline silicon film and the process for forming the oxide film can be performed alternately in the same chamber.

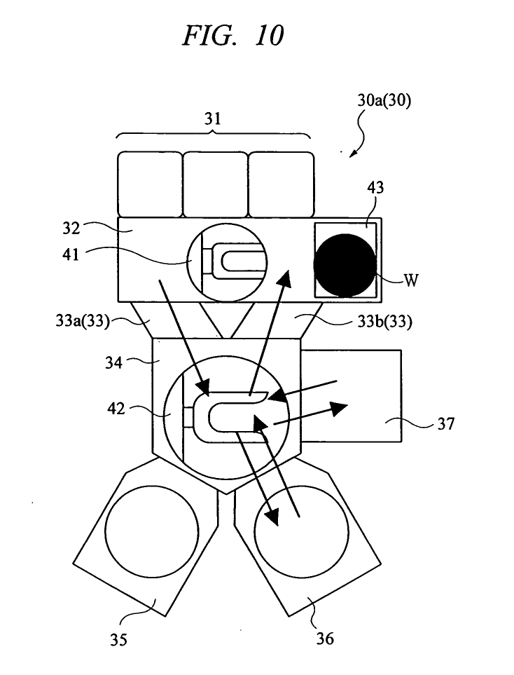

FIG. 10 shows the configuration in which an abnormal-growth-suppression film forming chamber 37 is additionally provided to the transfer chamber 34. As shown in FIG. 10, the abnormal-growth-suppression film forming chamber 37 is provided between the process chamber 36 and the homeward load lock 33b. In the abnormal-growth-suppression film forming chamber 37, the oxide film can be formed on the surface of the polycrystalline silicon formed on the wafer in the process chambers 35 and 36. The oxygen supply system for supplying oxygen into the chamber and the exhaust system for exhausting oxygen from the chamber are provided in the abnormal-growth-suppression film forming chamber 37. Furthermore, it is also possible to provide a heater so as to perform the oxidation process at higher temperature and in a short time.

In the foregoing, the invention made by the inventors of the present invention has been concretely described based on the embodiments. However, it is needless to say that the present invention is not limited to the foregoing embodiments and various modifications and alterations can be made within the scope of the present invention.

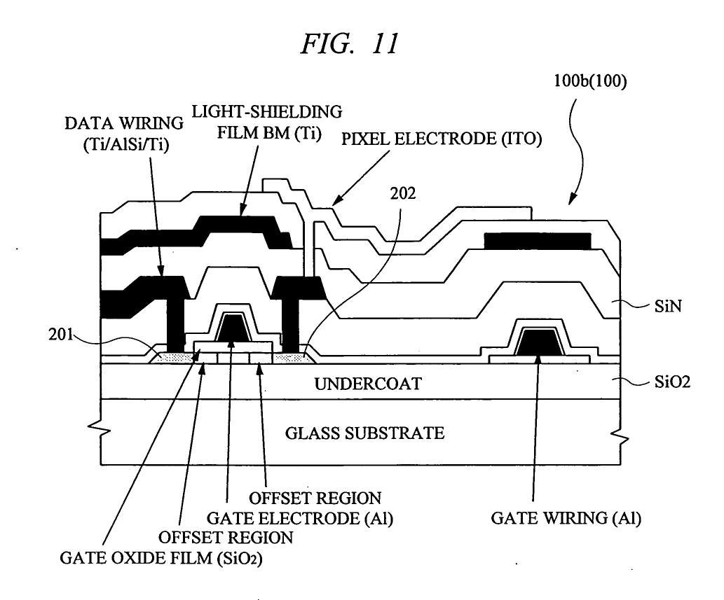

For example, the case where the manufacturing method of a semiconductor device according to the present invention is applied to the semiconductor device 100 to be used as a flash memory 100a has been described. However, the manufacturing method of a semiconductor device according to the present invention is applied to the semiconductor device 100 to be used as a thin film transistor (TFT) 100b used in a liquid crystal display as shown in FIG. 11.

The thin film transistor 100b shown in FIG. 11 is used as a pixel provided at the intersection between a gate line and a data line from the gate driver and the source driver. In FIG. 11, an undercoat made of SiO₂ is provided on a glass substrate and a semiconductor layer is formed on the undercoat. As shown in FIG. 11, as the semiconductor layer on the undercoat, a source region 201, a drain region 202, a gate oxide film, a gate electrode, a gate wiring, a data wiring, a pixel electrode, a light-shielding film and the like are provided.

Of the structure of the semiconductor layer described above in the thin film transistor 100b, the source region 201 and the drain region 202 are formed by patterning the phosphorus-doped polycrystalline silicon formed on the undercoat. Since the abnormal growth frequently occurs also on the polycrystalline silicon formed on the undercoat, it is preferable to form the abnormal growth suppression film made of a thin oxide film immediately after forming the polycrystalline silicon.

Note that, in the foregoing embodiments, it has been described that the oxide film formed on the polycrystalline silicon film has a function as the abnormal growth suppression film on the surface thereof. However, in addition to the effect described above, advantageous effects such as the improvement of the hydrophilic properties on the polycrystalline silicon surface, the protection from particle adhesion on the polycrystalline silicon surface and the like can be achieved by forming the above-described oxide film.

Therefore, the oxidation process in the step S100 in FIG. 5 for forming the oxide film on the polycrystalline silicon formed on the wafer can be employed for the purpose of not only the abnormal growth suppression but also the improvement of the hydrophilic properties or the protection from particle adhesion. Of course, it is also possible to use the step S100 for the purpose of all or some of the abnormal growth suppression, the improvement of the hydrophilic properties, and the protection from particle adhesion.

In the solution, the particle adhering to the wafer surface is greatly influenced by a zeta potential of the surface. That is, the adhesion of particle largely differs depending on whether the surface zeta potential is positive or negative.

Silicon is charged negatively in any solution with any pH value. However, other materials including the foreign matter such as a particle are charged positively in the acid solution (pH 5 or less). More specifically, the silicon surface has the high potential for the adhesion of the foreign matter in the acid solution. However, if the surface oxidation of silicon is performed, since the silicon oxide formed by the surface oxidation is charged positively, the surface potential similar to that of the foreign matter can be acquired. Therefore, the potential for the adhesion of the foreign matter can be greatly reduced.

Also, with respect to the improvement of the hydrophilic properties, the watermark (defect of circular spot) formed as SiO₂ on the silicon surface can be effectively suppressed. The watermark is formed when oxygen in the air is melt into the water drop on the wafer surface and left on the silicon surface as SiO₂ in the dry process which is the final process of the so-called wet process using solution including the cleaning process and the patterning (resist coating and development). If the hydrophilic properties of the silicon surface can be improved, since the water drop is hardly formed on the silicon, the occurrence of the watermark can be suppressed.

That is, the oxide film formed on the silicon surface is quite effective for suppressing the adhesion of the foreign matter and the occurrence of watermark when the so-called wet process using solution including the cleaning process and the patterning (resist coating and development) is performed on the silicon surface.

Note that the method of forcibly forming the oxide film described in the foregoing embodiments is not limited to the case where polycrystalline silicon is formed on the wafer. Of course, it can be effectively applied to the case where amorphous silicon is formed on the wafer.

The present invention can be effectively used as a technology for suppressing the abnormal growth of silicon in a manufacturing method of a semiconductor device including a step of forming a polycrystalline silicon film.

1. A manufacturing method for a semiconductor device, comprising the steps of:
forming a polycrystalline or amorphous silicon layer over a wafer; and
forming a thin silicon oxide film functioning to suppress surface abnormality of said silicon layer on a surface of said silicon layer immediately after forming said silicon layer.

2. The manufacturing method for a semiconductor device according to claim 1,
wherein said silicon oxide film has a thickness of less than 2.0 nm.

3. The manufacturing method for a semiconductor device according to claim 1,
wherein surface oxidation of said silicon layer is performed using ozone water or chemical solution containing the ozone water.

4. The manufacturing method for a semiconductor device according to claim 1,
wherein surface oxidation of said silicon layer is performed using hydrogen peroxide solution or chemical solution containing the hydrogen peroxide solution.

5. The manufacturing method for a semiconductor device according to claim 1,
wherein surface oxidation of said silicon layer is performed using oxidation means provided in a silicon forming apparatus for forming said silicon layer on the wafer.

6. A manufacturing method for a semiconductor device, comprising the steps of:
setting a time between a step of forming a polycrystalline or amorphous silicon layer over a wafer and a step of performing a next process to be short enough to suppress occurrence of surface abnormality of said silicon layer.

7. A manufacturing method for a semiconductor device, comprising the steps of:
forming a polycrystalline or amorphous silicon layer over a wafer, and forcibly forming an oxide film before surface abnormality occurs on a surface of said silicon layer.

8. The manufacturing method for a semiconductor device according to claim 7,
wherein said silicon oxide film has a thickness of less than 2.0 nm.

9. A semiconductor manufacturing apparatus comprising:
silicon forming means for forming a silicon layer over a wafer; and
oxidation means for oxidizing a surface of said silicon layer formed by said silicon forming means.

10. The semiconductor manufacturing apparatus according to claim 9,
wherein said oxidation means is provided in a load lock.

11. The semiconductor manufacturing apparatus according to claim 9,
wherein said oxidation means is provided in a chamber other than a chamber having said silicon forming means.
